(19) United States
(12) Patent Application Publication
(10) Pub. No.: US 2025/0338766 A1
(43) Pub. Date: Oct. 30, 2025

(54) COMPOSITE MATERIAL AND PHOTOELECTRIC DEVICE

(71) Applicant: TCL Technology Group Corporation, Huizhou (CN)

(72) Inventor: Shengjuan FU, Huizhou (CN)

(73) Assignee: TCL Technology Group Corporation, Huizhou (CN)

(21) Appl. No.: 19/190,568

(22) Filed: Apr. 25, 2025

(30) Foreign Application Priority Data
Apr. 28, 2024 (CN) 202410525258.7

(51) Int. Cl. H10K 85/20; C09K 11/88; H10K 50/115; H10K 85/10

(52) U.S. Cl. CPC H10K 85/20; C09K 11/883; H10K 50/115; H10K 85/115; H10K 85/151

(57) ABSTRACT

The present disclosure discloses composite material and photoelectric device. The composite material includes a host material and a modification material, wherein the host material includes semiconductor material and the modification material includes doped carbon dots. The composite material provided by the present disclosure has good performance.

This application claims priority to Chinese Application No. 202410525258.7, entitled “COMPOSITE MATERIAL, PREPARATION METHOD THEREOF, PHOTOELECTRIC DEVICE AND DISPLAY DEVICE”, filed on Apr. 28, 2024. The entire disclosures of the above application are incorporated herein by reference.

### TECHNICAL FIELD

The present disclosure relates to a field of display technologies, and more particularly, to composite material and photoelectric device.

### BACKGROUND

Semiconductor material is a kind of electronic material with semiconductor properties, whose conductivity is between conductor and insulator. And semiconductor material could be used to make semiconductor devices and integrated circuits. The properties of semiconductor materials, such as high temperature resistance, are poor and need to be further improved.

### Technical Solution

In view of this, the present disclosure provides a composite material and a photoelectric device.

The present disclosure provides a composite material, including: a host material; and a modification material; wherein the host material includes semiconductor material and the modification material includes doped carbon dots.

The present disclosure provides a photoelectric device, including: an anode; a cathode; a functional layer, between the anode and the cathode; wherein a material of the functional layer includes composite material, and the composite material includes a host material and a modification material, the host material includes semiconductor material, and the modification material includes first doped carbon dots.

The present disclosure provides a photoelectric device, including: an anode; a cathode; a functional layer, between the anode and the cathode, and includes a plurality of sub-functional layers; and an interface layer which include one or more of a first interface layer located between the anode and the functional layer, a second interface layer located between the functional layer and the cathode and a third interface layer located between two adjacent the sub-functional layers; and a material of the first interface layer includes second doped carbon dots, a material of the second interface layer includes third doped carbon dots, and a material of the third interface layer includes fourth doped carbon dots.

The composite material provided by the present disclosure has good performance.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a flowchart of a method for preparing a composite material according to an embodiment of the present disclosure.

FIG. 2 is a schematic diagram of the structure of a photoelectric device according to an embodiment of the present disclosure.

FIG. 3 is a schematic diagram of the structure of a photoelectric device according to another embodiment of the present disclosure.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

Additionally, in the description of the present disclosure, the term “comprising/including” means “comprising/including but not limited to.” Various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

The present disclosure discloses a composite material. The composite material includes a host material and a modification material, wherein the host material includes semiconductor material and the modification material includes doped carbon dots.

In the composite material provided by this present disclosure, the modification material includes doped carbon dots. The doped carbon dots have many advantages such as good water solubility, low toxicity, environmental friendliness, wide source of raw materials, low cost and so on. At the same time, the doped carbon dots also have good electrical conductivity, thermal conductivity and rich active groups. The introduction of the doped carbon dots into the composite material could significantly improve the carrier mobility, heat dissipation and high temperature stability of the composite material. The doping carbon dots could also passivate the defects of semiconductor material and improve the fluorescence quantum yield of semiconductor material.

In some embodiments, a mass ratio of the host material to the modification material is (5-50): 1, such as 10:1, 15:1, 20:1, 25:1, 30:1, 35:1, 40:1, 45:1, etc. Within the range of the mass ratio, it is beneficial for the modification material to passivate the defects of the host material and improve the conductivity, heat dissipation, stability and other properties of the host material.

In some embodiments, the doped carbon dots include carbon dots and doping element.

In some embodiments, an average particle size of the carbon dots ranges between 2 nm-10 nm, such as 3 nm, 4 nm, 5 nm, 6 nm, 7 nm, 8 nm, 9 nm, etc.

In some embodiments, the doping element is selected from one or more of alkali metal, alkaline earth metal, IIB group element and VIA group element.

The alkali metal includes K.

The alkaline earth metal includes Mg.

Both the alkali metal and the alkaline earth metal could further improve the high temperature resistance of the composite material.

The IIB group element includes one or more of Cd and Zn.

The VIA group element includes one or more of Se and S.

The compatibility of the IIB group element and the VIA group element is good, which could significantly promote the compatibility of the carbon dots with the host material.

In some embodiments, in the doped carbon dots, a doping mass fraction of the doping element ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. It could be understood that within the range of the doping mass fraction, the doping element could improve the high temperature resistance of the composite material and/or promote the compatibility of the modification material with the host material.

In some embodiments, the doping element in the doped carbon dots includes at least one of the alkali metal, the alkaline earth metal and at least one of the IIB group element and the VIA group element, a mass ratio of the mass sum of the alkali metal and the alkaline earth metal to the mass sum of the IIB group element and the VIA group element is (1-3):(1-3), such as 1: 1, 1:2, 1:3, 2:1, 3:1, etc. Within the range of the mass ratio, the compatibility of the doped carbon dots with the host material is facilitated, and the high temperature resistance of the composite material is improved. In other words, the doping elements could coordinate the beneficial effects of improving the high temperature resistance of the composite material and promoting compatibility.

In some embodiments, an active group is connected with the doped carbon dots.

Further, the active group is selected from one or more of amino group, carboxyl group, hydroxyl group, sulfhydryl group, carbonyl group, quinone group, pyrrole group and pyridyl group. It could be understood that the active group could passivate the defects of the composite material and improve the carrier mobility and fluorescence quantum yield of the composite material.

In some embodiments, the semiconductor material includes one or more of n-type semiconductor material, p-type semiconductor material and luminescent material.

It should be noted that the n-type semiconductor material is material known in the art for electronic functional layer, the p-type semiconductor material is material known in the art for hole functional layer, and the luminescent material is material known in the art for luminescent layer.

The doped carbon dots are compounded with the n-type semiconductor material, which could improve the electron mobility, heat dissipation and high temperature stability of the composite material. The doped carbon dots are compounded with the p-type semiconductor material, which could improve the hole mobility, heat dissipation and high temperature stability of the composite material. The doped carbon dots are compounded with the luminescent material, which could passivate the defects of the luminescent material and improve the fluorescence quantum yield of the luminescent material. When the composite material is applied to the functional layer of a photoelectric device, a luminous efficiency of the photoelectric device could be effectively improved, a voltage of the photoelectric device could be stabilized, and a voltage increase could be reduced.

In some embodiments, the n-type semiconductor material is selected from one or more of 8-hydroxyquinoline aluminum, 1,3,5-tris (1-phenyl-1H-benzimidazole-2-yl)benzene, 4,7-diphenyl-1,10-o-phenanthroline, 2,9-dimethyl-4,7-diphenyl-1,10-phenanthroline, 3-(biphenyl-4-yl)-5-(4-tert-butylphenyl)-4-phenyl-4H-1,2,4-triazole, bis(2-methyl-8-hydroxyquinoline-N1,O8)-(1,1′-biphenyl-4-hydroxy) aluminium, first doped metal oxide particle, bis(2-methyl-8-hydroxyquinoline-N1,O8)-(1,1′-biphenyl-4-hydroxy) aluminum, 2,2′-(1,3-phenyl) bis [5-(4-tert-butylphenyl)-1,3,4-oxadiazole], tri [2,4,6-trimethyl-3-(3-pyridyl)phenyl] borane, tetrakis [(m-pyridyl)-benzene-3-yl] biphenyl, 3,3′-[5′-[3-(3-pyridyl)phenyl] [1,1′: 3′, 1′-terphenyl]-3,3″-diyl] bipyridine, 1,3-bis(3,5-bipyridine-3-yl phenyl)benzene, n,n′-bis(naphthalene-1-yl)-n,n′-bis(phenyl)benzidine, first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, the p-type semiconductor material is selected from one or more of 4,4′-N,N′-dicarbazolyl-biphenyl, N,N′-diphenyl-N, N′-bis(1-naphthyl)-1,1′-biphenyl)-4,4′-diamine, N,N′-bis(3-methylphenyl)-N, N′-bis(phenyl)-spiro, N,N′-bis(4-(N,N′-diphenyl-amino)phenyl)-N,N′-diphenylbenzidine, 4,4′,4′-tris (N-carbazolyl)-triphenylamine, 4,4′,4′-tris (carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4, 4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly (9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N, N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

It should be noted that when the n-type semiconductor material and the p-type semiconductor material are inorganic materials, the doped carbon dots could passivate the defects of the inorganic materials. When the n-type semiconductor material and the p-type semiconductor material are organic materials, the active groups on the doped carbon dots could be crosslinked with the organic materials, so that the compatibility between the doped carbon dots and the organic materials is increased, the carrier migration efficiency is improved, and the heat dissipation of the composite material is improved.

In some embodiments, the luminescent material is selected from one or more of organic luminescent material and quantum dot luminescent material.

A material of the organic luminescent material is selected from one or more of CBP:Ir(mppy)₃ (4,4′-bis(N-carbazole)-1,1′-biphenyl: tris [2-(p-tolyl) pyridine iridium (III)]), TCTX:Ir(mmpy) (4,4′,4″-tris(carbazole-9-yl)triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B-N covalent bonds, HLCT (hybrid local charge transfer excited state) materials and Exciplex luminescent materials.

The quantum dot luminescent material could be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot could be respectively selected from but not limited to one or more of second II-VI compound, second IV-VI compound, second III-V compound and I-III-VI compound. A shell layer of the core-shell structure quantum dot includes one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AIP, AIAs, AlSb, InN, InP, InAs, InSb, GaNP, GaNAs, GaNSb, GaPAs, GaPSb, AlNP, AlNAs, AlNSb, AIPAS, AIPSb, InNP, InNAs, InNSb, InPAs, InPSb, GaAINP, GaAlNAs, GaAINSb, GaAlPAS, GaAIPSb, GalnNP, GalnNAs, GalnNSb, GalnPAs, GalnPSb, InAINP, InAINAs, InAINSb, InAIPAsand InAIPSb. The I-III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻. The general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.

In some embodiments, the doped carbon dots and the quantum dot luminescent material are connected through the active group. In other words, the composite material includes a structure doped with carbon dots-active group-quantum dot luminescent material, and specifically, the active group could be connected with the doped carbon dots and the quantum dot luminescent material through coordination bonds, chelating bonds and the like. The doped carbon dots surround the surface of the quantum dot luminescent material, and the active group are beneficial to closely connecting the doped carbon dots and the quantum dot luminescent material, so that the doped carbon dots could more effectively passivate the defects of the quantum dot luminescent material.

In some embodiments, the composite material includes the doped carbon dots and the luminescent material, the doping element of the doped carbon dots are the same as element in the luminescent material. Thus, the compatibility between the doped carbon dots and the luminescent material is facilitated.

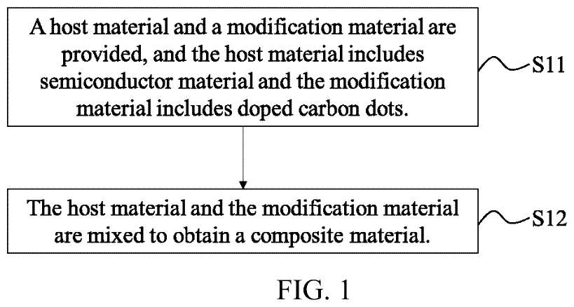

Referring to FIG. 1, the present disclosure proposes a preparation method of a composite material 100 which includes step S11-S12.

In step S11, a host material and a modification material are provided, and the host material includes semiconductor material and the modification material includes doped carbon dots.

In step S12, the host material and the modification material are mixed to obtain a composite material.

In some embodiments, a method of the host material and the modification material are mixed includes step S121-S122.

In step S121, the host material, the modification material and a solvent are provided and mixed to obtain a mixed solution.

In step S122, ultrasonic treatment is carried out on the mixed solution to obtain the composite material.

In some embodiments, in the mixed solution, a mass ratio of the host material to the modification material is (5-50): 1, such as 10:1, 15:1, 20:1, 25:1, 30:1, 35:1, 40:1, 45:1, etc. Within the range of the mass ratio, it is beneficial for the modification material to passivate the defects of the host material and improve the conductivity, heat dissipation, stability and other properties of the host material.

In some embodiments, the semiconductor material includes one or more of n-type semiconductor material, p-type semiconductor material and luminescent material.

In some embodiments, the semiconductor material is the p-type semiconductor material, and a mass concentration of the p-type semiconductor material in the mixed solution ranges between 4 mg/mL-15 mg/mL, such as 5 mg/mL, 6 mg/mL, 8 mg/mL, 10 mg/ml, 12 mg/mL, etc.

In some embodiments, the semiconductor material is the n-type semiconductor material, and a mass concentration of the n-type semiconductor material in the mixed solution ranges between 10 mg/mL-40 mg/mL, such as 15 mg/mL, 20 mg/mL, 25 mg/ml, 30 mg/ml, 35 mg/ml, etc.

In some embodiments, the semiconductor material is the luminescent material, and a mass concentration of the luminescent material in the mixed solution ranges between 10 mg/mL-40 mg/mL, such as 15 mg/mL, 20 mg/mL, 25 mg/ml, 30 mg/mL, 35 mg/mL, etc.

Within the mass concentration range, it is beneficial to the uniform dispersion of the semiconductor material.

In some embodiments, the solvent is selected from one or more of chlorobenzene, diethylene glycol monobutyl ether, trimethoxybutanol, triethylene glycol monobutyl ether, diethylene glycol dimethyl ether, methanol, ethanol, propanol, butanol, ethylene glycol, isopropanol, glycerol, dimethyl sulfoxide, acetone, acetophenone, tetrahydrofuran, N,N-dimethylformamide, ethyl acetate, pyrrole, butyric acid and cresol.

In some embodiments, a frequency of the ultrasonic treatment ranges between 20 kHz-40 kHz, such as 22 kHz, 25 kHz, 28 kHz, 30 kHz, 32 kHz, 35 kHz, 38 kHz, etc. A time of the ultrasonic treatment ranges between 10 min-30 min, such as 12 min, 15 min, 18 min, 20 min, 22 min, 25 min, 28 min, etc. In this way, under the ultrasonic treatment condition, it is beneficial to the uniform mixing of the host material and the modification material.

It should be noted that when the host material is the quantum dot luminescent material, a surface of the quantum dot luminescent material contains ligand, which is selected from one or more of conventional ligand known in the art, such as acid ligand, phosphine ligand, amine ligand and thiol ligand. The acid ligand is selected from one or more of oleic acid, sulfhydrylacetic acid and sulfhydrylpropionic acid. The phosphine ligand is selected from one or more of trioctylphosphine, trioctylphosphine oxide and tributylphosphine. The amine ligand is selected from oleylamine. The thiol ligand is selected from one or more of 1,2-ethanedithiol, propanethiol, butanethiol, octanethiol, dodecyl mercaptan, octadecyl mercaptan, phenylmercaptan, 1,2-phenylmercaptan, 1,3-phenylmercaptan and 1,4-phenylmercaptan. When the doped carbon dots are mixed with the quantum dot luminescent material, the ligand on the surface of the quantum dot luminescent material falls off, and one end of the active group is connected with the doped carbon dots, and the other end is connected with the quantum dot luminescent material to form the composite material.

The preparation method of the composite material provided by the present disclosure is simple in operation and low in cost, and could effectively prepare the composite material.

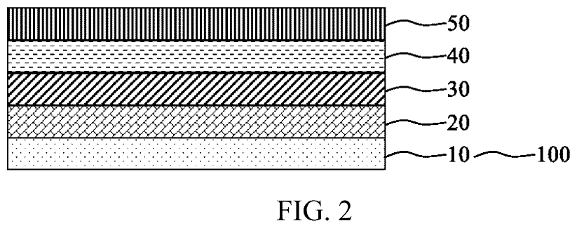

Referring to FIG. 2, the present disclosure discloses a photoelectric device 100, including:
an anode 10;
a cathode 50;
a functional layer, between the anode 10 and the cathode 50; wherein a material of the functional layer includes composite material, and the composite material includes a host material and a modification material, the host material includes semiconductor material, and the modification material includes first doped carbon dots.

In the photoelectric device 100 provided by the present disclosure, the composite material containing doped carbon dots is applied to the functional layer, which could effectively improve the luminous efficiency of the photoelectric device 100, stabilize the voltage of the photoelectric device 100, and reduce the voltage increase.

In some embodiments, a material of the anode 10 and the cathode 50 is each independently selected from one or more of metal, carbon material and metal oxide. The metal is selected from one or more of Al, Ag, Cu, Mo, Au, Ba, Ca, Y b and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, the functional layer includes sub-functional layer, and the sub-functional layer includes one or more of a hole functional layer 20, a luminescent layer 30 and an electronic functional layer 40, wherein the hole functional layer 20 is arranged between the anode 10 and the luminescent layer 30, and the electronic functional layer 40 is arranged between the luminescent layer 30 and the cathode 50.

It could be understood that the material of the functional layer includes the composite material, that is, the material of at least one of the hole functional layer 20, the luminescent layer 30 and the electronic functional layer 40 includes the composite material, and the host material in the composite material is an n-type semiconductor material, a p-type semiconductor material or a luminescent material.

In some embodiments, when the material of the hole functional layer 20 includes the composite material, the host material in the composite material is the p-type semiconductor material. When the material of the hole functional layer 20 does not include the composite material, the material of the hole functional layer 20 may be a p-type semiconductor material, that is, it does not contain doped carbon dots modification material.

In some embodiments, when the material of the luminescent layer 30 includes the composite material, the host material in the composite material is the luminescent material. When the material of the luminescent layer 30 does not include the composite material, the material of the luminescent layer 30 may be a luminescent material, that is, it does not contain doped carbon dots modification material.

In some embodiments, when the material of the electronic functional layer 40 includes the composite material, the host material in the composite material is the n-type semiconductor material. When the material of the electronic functional layer 40 does not include the composite material, the material of the electronic functional layer 40 may be an n-type semiconductor material, that is, it does not contain doped carbon dots modification material.

It could be understood that the material of the hole functional layer 20 is a p-type semiconductor material, the material of the electronic functional layer 40 is an n-type semiconductor material, and the material of the light-emitting layer 30 is a quantum dot light-emitting material. Adding the modification material to the p-type semiconductor material and the n-type semiconductor material could promote the compatibility of the hole functional layer 20, the electronic functional layer 40 and the luminescent layer 30, promote the migration and recombination of carriers, and improve the device efficiency.

In other embodiments, the photoelectric device 100 further includes an interface layer 60; the functional layer includes a plurality of sub-functional layers; and the interface layer 60 includes one or more of a first interface layer 63 located between the anode 10 and the functional layer, a second interface layer 64 located between the functional layer and the cathode 50 and a third interface layer located between two adjacent the sub-functional layers; and a material of the first interface layer 63 includes second doped carbon dots, a material of the second interface layer 64 includes third doped carbon dots, and a material of the third interface layer includes fourth doped carbon dots.

In other embodiments, the third interface layer includes at least one interface sub-layer. In any sub-functional layer, interface layer and interface sub-layer, the average particle size and active group of carbon dots in doped carbon dots are the same or different, and the material and doping mass fraction of doping elements doped in carbon dots are the same or different.

In some embodiments, the hole functional layer 20 includes one or more of a hole injection layer 21 and a hole transport layer 22, and the hole injection layer 21 is located between the anode 10 and the hole transport layer 22. The electronic functional layer 40 includes one or more of an electronic injection layer 42 and an electronic transport layer 41, and the electronic injection layer 42 is located between the electronic transport layer 41 and the cathode 50.

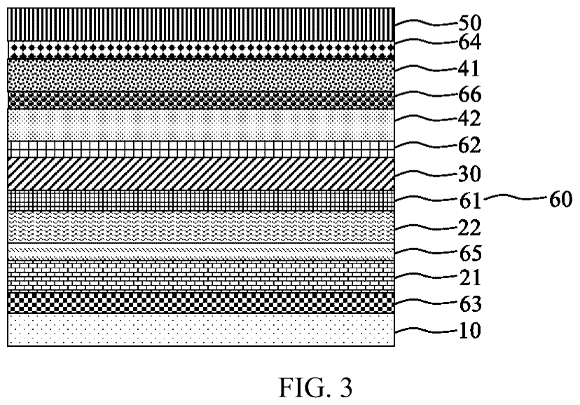

Referring to FIG. 3, the third interface layer includes one or more of a first interface sub-layer 65 between the hole injection layer 21 and the hole transport layer 22, a second interface sub-layer 61 between the hole transport layer 22 and the luminescent layer 30, a third interface sub-layer 62 between the luminescent layer 30 and the electronic transport layer 41, and a fourth interface sub-layer 66 between the electronic transport layer 41 and the electronic injection layer 42.

In some embodiments, a doping mass fraction of the doping element in the first doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. It could be understood that for the sub-functional layer, within the range of the doping mass fraction, the doping element could improve the performance of the composite material, thereby improving the carrier mobility, fluorescence quantum yield and stability of the functional layer.

A doping mass fraction of the doping element in the second doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. A doping mass fraction of the doping element in the third doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. A doping mass fraction of the doping element in the fourth doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. For the interface layer 60 and the interface sub-layer, within the range of the doping mass fraction, the interface layer 60 and the interface sub-layer could promote the interface compatibility among the film layers in the photoelectric device 100, further promote the carrier transport to the luminescent layer 30 for composite light emission, and improve the light-emitting efficiency of the photoelectric device 100.

In some embodiments, a doping element in the first doped carbon dots, a doping element in the second doped carbon dots, a doping element in the third doped carbon dots, and a doping element in the fourth doped carbon dots is each independently selected from one or more of alkali metal, alkaline earth metal, IIB group element and VIA group element. The alkali metal includes K. The alkaline earth metal includes Mg. The IIB group element includes one or more of Cd and Zn. The VIA group element includes one or more of Se and S.

In some embodiments, a thickness of the first interface layer 63 ranges between 5 nm-20 nm, such as 6 nm, 8 nm, 10 nm, 12 nm, 14 nm, 16 nm, 18 nm, etc. In some embodiments.

In some embodiments, a thickness of the second interface layer 64 ranges between 5 nm-20 nm, such as 6 nm, 8 nm, 10 nm, 12 nm, 14 nm, 16 nm, 18 nm, etc.

In some embodiments, a thickness of the third interface layer ranges between 5 nm-20 nm, such as 6 nm, 8 nm, 10 nm, 12 nm, 14 nm, 16 nm, 18 nm, etc.

In some embodiments, a thickness of the first interface sub-layer 65 ranges between 5 nm-20 nm, such as 6 nm, 8 nm, 10 nm, 12 nm, 14 nm, 16 nm, 18 nm, etc.

In some embodiments, a thickness of the second interface sub-layer 61 ranges between 5 nm-20 nm, such as 6 nm, 8 nm, 10 nm, 12 nm, 14 nm, 16 nm, 18 nm, etc.

In some embodiments, a thickness of the third interface sub-layer 62 ranges between 5 nm-20 nm, such as 6 nm, 8 nm, 10 nm, 12 nm, 14 nm, 16 nm, 18 nm, etc.

In some embodiments, a thickness of the fourth interface sub-layer 66 ranges between 5 nm-20 nm, such as 6 nm, 8 nm, 10 nm, 12 nm, 14 nm, 16 nm, 18 nm, etc.

Within the thickness range of the surface layer 60 and the interface sub-layer, the carrier transmission path is appropriate, which could effectively adjust the interface compatibility between the film layers in the photoelectric device 100, promote the carrier transmission and composite luminescence, and improve the performance of the photoelectric device 100.

In some embodiments, the photoelectric device 100 includes a light emitting diode.

Referring to FIG. 3, the present disclosure discloses another photoelectric device 100, including:
an anode 10;
a cathode 50;
a functional layer, between the anode 10 and the cathode 50, and includes a plurality of sub-functional layers; and
an interface layer 60 which include one or more of a first interface layer 63 located between the anode 10 and the functional layer, a second interface layer 64 located between the functional layer and the cathode 50 and a third interface layer located between two adjacent the sub-functional layers; and a material of the first interface layer 63 includes second doped carbon dots, a material of the second interface layer 64 includes third doped carbon dots, and a material of the third interface layer includes fourth doped carbon dots.

In the photoelectric device 100 provided by the present disclosure, the interface layer 60 formed by doped carbon dots is arranged in the photoelectric device 100, which could effectively improve the luminous efficiency of the photoelectric device 100, stabilize the voltage of the photoelectric device 100, and reduce the voltage increase.

In some embodiments, a material of the anode 10 and the cathode 50 is each independently selected from one or more of metal, carbon material and metal oxide. The metal is selected from one or more of Al, Ag, Cu, Mo, Au, Ba, Ca, Y b and Mg. The carbon material is selected from one or more of graphite, carbon nanotubes, graphene and carbon fiber. The metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO. The composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂. Where “/” represents a laminated structure, for example, AZO/Ag/AZO represents a composite electrode including an AZO layer, an Ag layer and an AZO layer which are sequentially laminated.

In some embodiments, the functional layer includes sub-functional layer, and the sub-functional layer includes one or more of a hole functional layer 20, a luminescent layer 30 and an electronic functional layer 40, wherein the hole functional layer 20 is arranged between the anode 10 and the luminescent layer 30, and the electronic functional layer 40 is arranged between the luminescent layer 30 and the cathode 50.

In some embodiments, a material of the electronic functional layer 40 is selected from one or more of 8-hydroxyquinoline aluminum, 1,3,5-tris (1-phenyl-1H-benzimidazole-2-yl)benzene, 4,7-diphenyl-1,10-o-phenanthroline, 2,9-dimethyl-4,7-diphenyl-1,10-phenanthroline, 3-(biphenyl-4-yl)-5-(4-tert-butylphenyl)-4-phenyl-4H-1,2,4-triazole, bis(2-methyl-8-hydroxyquinoline-N1,O8)-(1,1′-biphenyl-4-hydroxy) aluminium, first doped metal oxide particle, bis(2-methyl-8-hydroxyquinoline-N1,O8)-(1,1′-biphenyl-4-hydroxy) aluminum, 2,2′-(1,3-phenyl) bis [5-(4-tert-butylphenyl)-1,3,4-oxadiazole], tri [2,4,6-trimethyl-3-(3-pyridyl)phenyl] borane, tetrakis [(m-pyridyl)-benzene-3-yl] biphenyl, 3,3′-[5′-[3-(3-pyridyl)phenyl] [1,1′: 3′, 1′-terphenyl]-3,3″-diyl] bipyridine, 1,3-bis(3,5-bipyridine-3-yl phenyl)benzene, n,n′-bis(naphthalene-1-yl)-n,n′-bis(phenyl)benzidine, first doped metal oxide particle, first undoped metal oxide particle, IIB-VIA semiconductor material, IIIA-VA semiconductor material and IB-IIIA-VIA semiconductor material. A material of the first undoped metal oxide particle is selected from one or more of ZnO, TiO₂, SnO₂, ZrO₂ and Ta₂O₅. A metal oxide in the first doped metal oxide particle is selected from one or more of ZnO, TiO₂, SnO₂, ZrO₂, Ta₂O₅ and Al₂O₃. A doping element in the first doped metal oxide particle is selected from one or more of Al, Mg, Li, Mn, Y, La, Cu, Ni, Zr, Ce, In and Ga. The IIB-VIA semiconductor material is selected from one or more of ZnS, ZnSe and CdS. The IIIA-VA semiconductor material is selected from one or more of InP and GaP. The IB-IIIA-VIA family semiconductor material is selected from one or more of CuInS and CuGaS.

In some embodiments, a material of the hole functional layer 20 is selected from one or more of 4,4′-N,N′-dicarbazolyl-biphenyl, N,N′-diphenyl-N, N′-bis(1-naphthyl)-1,1′-biphenyl)-4,4′-diamine, N,N′-bis(3-methylphenyl)-N,N′-bis(phenyl)-spiro, N,N′-bis(4-(N,N′-diphenyl-amino) phenyl)-N,N′-diphenylbenzidine, 4,4′,4′-tris (N-carbazolyl)-triphenylamine, 4,4′,4′-tris (carbazole-9-yl)triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4, 4′-(N-(4-sec-butylphenyl) diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly (9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride.

In some embodiments, a material of the luminescent layer 30 is selected from one or more of organic luminescent material and quantum dot luminescent material.

A material of the organic luminescent material is selected from one or more of CBP:Ir(mppy)₃ (4,4′-bis(N-carbazole)-1,1′-biphenyl: tris [2-(p-tolyl) pyridine iridium (III)]), TCTX:Ir(mmpy) (4,4′,4″-tris(carbazole-9-yl)triphenylamine: tris [2-(p-tolyl) iridium pyridine]), diarylanthracene derivatives, stilbene aromatic derivatives, pyrene derivatives, fluorene derivatives, TBPe fluorescent materials, TTPX fluorescent materials, TBRb fluorescent materials, DBP fluorescent materials, delayed fluorescent materials, TTA materials, TADF (delayed thermal activation) materials, polymers containing B-N covalent bonds, HLCT (hybrid local charge transfer excited state) materials and Exciplex luminescent materials.

The quantum dot luminescent material could be selected from but not limited to one or more of single-structure quantum dot, core-shell quantum dot and perovskite-type semiconductor material.

A material of the single-structure quantum dot, a core material of the core-shell quantum dot and a shell material of the core-shell quantum dot could be respectively selected from but not limited to one or more of second II-VI compound, second IV-VI compound, second III-V compound and I-III-VI compound. A shell layer of the core-shell structure quantum dot includes one or more layers. The second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe. The second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe. The second III-V compound is selected from one or more of GaN, GaP, GaAs, GaSb, AlN, AIP, AIAs, AlSb, InN, InP, InAs, InSb, GaNP, GaNAs, GaNSb, GaPAs, GaPSb, AlNP, AlNAs, AlNSb, AIPAS, AIPSb, InNP, InNAs, InNSb, InPAs, InPSb, GaAINP, GaAlNAs, GaAINSb, GaAlPAS, GaAIPSb, GalnNP, GalnNAs, GalnNSb, GalnPAs, GalnPSb, InAINP, InAINAs, InAINSb, InAIPAs and InAIPSb. The I-III-VI compound is selected from one or more of CuInS₂, CuInSe₂ and AgInS₂.

As an example, the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe.

The perovskite semiconductor material is selected from one of doped or undoped inorganic perovskite semiconductor or organic-inorganic hybrid perovskite semiconductor. A general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻. The general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.

In other embodiments, the third interface layer includes at least one interface sub-layer. In any sub-functional layer, interface layer and interface sub-layer, the average particle size and active group of carbon dots in doped carbon dots are the same or different, and the material and doping mass fraction of doping elements doped in carbon dots are the same or different.

In some embodiments, the hole functional layer 20 includes one or more of a hole injection layer 21 and a hole transport layer 22, and the hole injection layer 21 is located between the anode 10 and the hole transport layer 22. The electronic functional layer 40 includes one or more of an electronic injection layer 42 and an electronic transport layer 41, and the electronic injection layer 42 is located between the electronic transport layer 41 and the cathode 50.

Referring to FIG. 3, the third interface layer includes one or more of a first interface sub-layer 65 between the hole injection layer 21 and the hole transport layer 22, a second interface sub-layer 61 between the hole transport layer 22 and the luminescent layer 30, a third interface sub-layer 62 between the luminescent layer 30 and the electronic transport layer 41, and a fourth interface sub-layer 66 between the electronic transport layer 41 and the electronic injection layer 42.

A doping mass fraction of the doping element in the second doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. A doping mass fraction of the doping element in the third doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. A doping mass fraction of the doping element in the fourth doped carbon dots ranges between 1 wt %-20 wt %, such as 2 wt %, 3 wt %, 4 wt %, 5 wt %, 6 wt %, 7 wt %, 8 wt %, 9 wt %, 10 wt %, 11 wt %, 12 wt %, 14 wt %, 15 wt %, 16 wt %, 17 wt %, 18 wt %, 19 wt %, etc. For the interface layer 60 and the interface sub-layer, within the range of the doping mass fraction, the interface layer 60 and the interface sub-layer could promote the interface compatibility among the film layers in the photoelectric device 100, further promote the carrier transport to the luminescent layer 30 for composite light emission, and improve the light-emitting efficiency of the photoelectric device 100.

In some embodiments, a doping element in the second doped carbon dots, a doping element in the third doped carbon dots, and a doping element in the fourth doped carbon dots is each independently selected from one or more of alkali metal, alkaline earth metal, IIB group element and VIA group element. The alkali metal includes K. The alkaline earth metal includes Mg. The IIB group element includes one or more of Cd and Zn. The VIA group element includes one or more of Se and S.

In some embodiments, a thickness of the first interface layer 63 ranges between 5 nm-20 nm, such as 6 nm, 8 nm, 10 nm, 12 nm, 14 nm, 16 nm, 18 nm, etc. In some embodiments.

In some embodiments, a thickness of the second interface layer 64 ranges between 5 nm-20 nm, such as 6 nm, 8 nm, 10 nm, 12 nm, 14 nm, 16 nm, 18 nm, etc.

In some embodiments, a thickness of the third interface layer ranges between 5 nm-20 nm, such as 6 nm, 8 nm, 10 nm, 12 nm, 14 nm, 16 nm, 18 nm, etc.

In some embodiments, a thickness of the first interface sub-layer 65 ranges between 5 nm-20 nm, such as 6 nm, 8 nm, 10 nm, 12 nm, 14 nm, 16 nm, 18 nm, etc.

In some embodiments, a thickness of the second interface sub-layer 61 ranges between 5 nm-20 nm, such as 6 nm, 8 nm, 10 nm, 12 nm, 14 nm, 16 nm, 18 nm, etc.

In some embodiments, a thickness of the third interface sub-layer 62 ranges between 5 nm-20 nm, such as 6 nm, 8 nm, 10 nm, 12 nm, 14 nm, 16 nm, 18 nm, etc.

In some embodiments, a thickness of the fourth interface sub-layer 66 ranges between 5 nm-20 nm, such as 6 nm, 8 nm, 10 nm, 12 nm, 14 nm, 16 nm, 18 nm, etc.

Within the thickness range of the surface layer 60 and the interface sub-layer, the carrier transmission path is appropriate, which could effectively adjust the interface compatibility between the film layers in the photoelectric device 100, promote the carrier transmission and composite luminescence, and improve the performance of the photoelectric device 100.

The present disclosure also discloses a display device, including the photoelectric device 100 in any of the above embodiments.

The display device could be a mobile terminal such as a TV set, a mobile phone, a tablet computer, a computer monitor, or a device with a display screen such as a game device, an Augmented Reality (AR) device, a Virtual Reality (VR) device, a data storage device, an audio playback device, a video playback device, and a wearable device, wherein the wearable device could be a smart bracelet, smart glasses, and a smart watch.

This present disclosure will be explained in detail by specific examples. The following examples are only partial examples of this present disclosure, and are not limited to this present disclosure.

### Example 1

This example provides a composite material which including n-type semiconductor material magnesium-doped zinc oxide (ZnMgO) and zinc-doped carbon dots, in which a mass fraction of zinc doping is 5%, and a preparation method of the composite material includes steps S1-S2.

In step S1, ZnMgO, zinc-doped carbon dots and ethanol are mixed to obtain a mixed solution. A mass ratio of the ZnMgO to the zinc-doped carbon dots is 30:1, and a mass concentration of ZnMgO in the mixed solution is 20 mg/ml.

In step S2, the mixed solution is ultrasonicated at 30 kHz for 20 min to obtain the composite material.

### Example 2

This example is basically the same as Example 1, only the difference is that in this example, the zinc-doped carbon dots is replaced by magnesium-doped carbon dots, in which a mass fraction of magnesium doping is 10%.

### Example 3

This example is basically the same as Example 1, only the difference is that in this example, a mass ratio of the ZnMgO to the zinc-doped carbon dots is 50:1.

### Example 4

This example is basically the same as Example 1, only the difference is that in this example, a mass ratio of the ZnMgO to the zinc-doped carbon dots is 5:1.

### Example 5

This example is basically the same as Example 1, only the difference is that in this example, in step S2, the mixed solution is ultrasonicated at 40 kHz for 20 min to obtain the composite material.

### Example 6

This example is basically the same as Example 1, only the difference is that in this example, in step S2, the mixed solution is ultrasonicated at 20 kHz for 20 min to obtain the composite material.

### Example 7

This example is basically the same as Example 1, only the difference is that in this example, in step S2, the mixed solution is ultrasonicated at 40 kHz for 30 min to obtain the composite material.

### Example 8

This example is basically the same as Example 1, only the difference is that in this example, in step S2, the mixed solution is ultrasonicated at 40 kHz for 10 min to obtain the composite material.

### Example 9

This example is basically the same as Example 1, only the difference is that in this example, the n-type semiconductor material ZnMgO is replaced by p-type semiconductor material TFB (poly [(9,9′-dioctyl fluorene-2,7-diyl)-co-(4, 4′-(N-(4-sec-butylphenyl) diphenylamine))]).

### Example 10

This example is basically the same as Example 9, only the difference is that in this example, the TFB is replaced by potassium-doped carbon dots, in which a mass fraction of potassium doping is 10%.

### Example 11

This example is basically the same as Example 9, only the difference is that in this example, the TFB is replaced by NiO.

### Example 12

This example is basically the same as Example 9, only the difference is that in this example, a mass ratio of the TFB to the zinc-doped carbon dots is 50:1.

### Example 13

This example is basically the same as Example 9, only the difference is that in this example, a mass ratio of the TFB to the zinc-doped carbon dots is 5:1.

### Example 14

This example is basically the same as Example 1, only the difference is that in this example, the n-type semiconductor material ZnMgO is replaced by luminescent material CdZnSe.

### Example 15

This example is basically the same as Example 14, only the difference is that in this example, the zinc-doped carbon dots are replaced by cadmium-doped carbon dots, in which a mass fraction of cadmium doping is 10%.

### Example 16

This example is basically the same as Example 14, only the difference is that in this example, a mass ratio of the CdZnSe to the zinc-doped carbon dots is 50:1.

### Example 17

This example is basically the same as Example 14, only the difference is that in this example, a mass ratio of the CdZnSe to the zinc-doped carbon dots is 5:1.

### Comparative Example 1

This comparative example provides a material, including n-type semiconductor material magnesium-doped zinc oxide ZnMgO.

### Comparative Example 2

This comparative example is basically the same as Example 1, only the difference is in this comparative example, the zinc-doped carbon dots are replaced by carbon dots.

### Comparative Example 3

This comparative example provides a material, including p-type semiconductor material TFB.

### Comparative Example 4

This comparative example is basically the same as Example 9, only the difference is in this comparative example, the zinc-doped carbon dots are replaced by carbon dots.

### Comparative Example 5

This comparative example provides a material, including p-type semiconductor material NiO.

### Comparative Example 6

This comparative example is basically the same as Example 11, only the difference is in this comparative example, the zinc-doped carbon dots are replaced by carbon dots.

### Comparative Example 7

This comparative example provides a material, including luminescent material CdZnSe.

### Comparative Example 8

This comparative example is basically the same as Example 14, only the difference is in this comparative example, the zinc-doped carbon dots are replaced by carbon dots.

A current density of the composite materials of Examples 1-13 and Comparative Examples 1-6, and a fluorescence quantum yield PLQY of the composite materials of Examples 14-17 and Comparative Examples 7-8 were tested respectively, and the results are shown in Table 1.

A testing method of current density is as follows: testing the current density-voltage curve of the semi-device of photoelectric device (single carrier transport film device HOD/EOD), obtaining the space charge limited current (SCLC) region in the current density-voltage curve, and obtaining the current density when the voltage is 1V. Wherein the structure of EOD is anode/quantum dot luminescent layer/electronic transport layer/cathode, and a material of the electronic transport layer are the composite materials of Examples 1-8 and Comparative Examples 1-2 respectively. The structure of HOD is anode/hole transport layer/quantum dot luminescent layer/cathode, and a material of the hole transport layer are the composite materials of Examples 9-13 and Comparative Examples 3-6 respectively.

The fluorescence quantum yield PLQY is measured by the steady-state fluorescence spectrometer of Edinburgh Instruments, the model of which is FS5, and the attachment for measuring the fluorescence quantum yield is SC-30.

TABLE 1

| | J@1 V | J@1 V | PLQY |
|---|---|---|---|
| | (mA/cm²) | (mA/cm²) | (%) |
| Example 1 | 50.3 | / | / |
| Example 2 | 67.8 | / | / |
| Example 3 | 52.5 | / | / |
| Example 4 | 50.7 | / | / |
| Example 5 | 55.6 | / | / |
| Example 6 | 47.9 | / | / |
| Example 7 | 57.8 | / | / |
| Example 8 | 45.4 | / | / |
| Comparative Example 1 | 20.4 | / | / |
| Comparative Example 2 | 27.1 | / | / |
| Example 9 | / | 56.6 | / |
| Example 10 | / | 68.2 | / |
| Example 11 | / | 45.7 | / |
| Example 12 | / | 62.3 | / |
| Example 13 | / | 50.1 | / |
| Comparative Example 3 | / | 15.9 | / |
| Comparative Example 4 | / | 20.5 | / |
| Comparative Example 5 | / | 11.2 | / |
| Comparative Example 6 | / | 16.3 | / |
| Example 14 | / | / | 35 |
| Example 15 | / | / | 39 |
| Example 16 | / | / | 36 |
| Example 17 | / | / | 33 |
| Comparative Example 7 | / | / | 25 |
| Comparative Example 8 | / | / | 30 |

It could be seen from Examples 1-8 and Comparative Examples 1-2 that the n-type semiconductor material is modified by doped carbon dots, compared with the n-type semiconductor material of Comparative Examples 1-2, the current density of the composite materials of Examples 1-8 is obviously improved, which means that the more charge passes through the unit area. In other words, the more electrons, the faster the electron migration rate. Within the range of the mass ratio of the n-type semiconductor material to the doped carbon dots provided by the present disclosure, the modification effect of doped carbon dots on n-type semiconductor material could be guaranteed. Compared with Example 1, the mixing frequency and time have little effect on the properties of the composite material, and both could effectively improve the current density and the electron mobility of the composite material. In Comparative Example 2, undoped carbon dots are used to modify the n-type semiconductor material, and the performance of the composite material is better than that of the n-type semiconductor material in Comparative Example 1, but it was still far worse than that of Examples 1-8.

From Examples 9-13 and Comparative Examples 3-6, it could be seen that doping the doped carbon dots into the p-type semiconductor material could significantly improve the current density, indicating that it has strong current output ability, reflecting the high hole migration efficiency, and the doped carbon dots could effectively improve the hole mobility of the composite material. The doped carbon dots could significantly improve both organic p-type semiconductor material and inorganic p-type semiconductor material. In Comparative Example 4 and Comparative Example 6, carbon dots directly modified the p-type semiconductor material, but the improvement effect is far less than that of doped carbon dots provided in the present disclosure.

From Examples 14-17 and Comparative Examples 7-8, it could be seen that doping the doped carbon dots into the luminescent material could effectively improve the fluorescence quantum yield of the luminescent material, that is because the doped carbon dots are connected with the luminescent material through active groups, which passivates the defects of the luminescent material. Especially in Example 15, the doped carbon dots are doped with cadmium, which promoted the compatibility between the doped carbon dots and the luminescent material, and the fluorescence quantum yield is significantly improved, which is obviously superior to the luminescent material and the luminescent material modified by the carbon dots.

### Photoelectric Device Example 1

This example provides a photoelectric device, and a preparation method of the photoelectric device includes steps S21-S28.

In step S21, an ITO conductive glass is cleaned by cleaning agent to remove the stains on the surface, then it is cleaned by ultrasonic in deionized water, acetone, anhydrous ethanol and deionized water for 20 min to remove the impurities on the surface, and finally it is blown dry with high-purity nitrogen to form an ITO anode with a thickness of 75 nm.

In step S22, PEDOT:PSS is spin-coated on the ITO anode at 2000 rpm for 30 s and baked at 100° C. for 20 min to form a hole injection layer with a thickness of 30 nm.

In step S23, TFB is spin-coated on the hole injection layer at 3000 rpm for 30 s and baked at 150° C. for 20 min to form a hole transport layer with a thickness of 40 nm.

In step S24, a quantum dot solution of CdZnSe with a mass concentration of 10 mg/ml is prepared and spun on the hole transport layer. A spin coating speed is 3000 rpm, a time is 30 s, and it is baked at 100° C. for 5 min to form a luminescent layer with a thickness of 25 nm.

In step S25, the composite material prepared by Example 1 is dissolved in ethanol and spin-coated on the luminescent layer at the rotating speed of 4000 rpm for 30 s, and then baked at 80° C. for 10 min to form an electronic transport layer with a thickness of 50 nm.

In step S26, an ethanol dispersion of TiO₂ is spin-coated on the electronic transport layer at 4000 rpm for 30 s, and then baked at 80° C. for 10 min to form an electronic injection layer with a thickness of 30 nm.

In step S27, Ag is evaporated on the electronic injection layer by thermal evaporation with a vacuum degree is not higher than 3×10−4 Pa, a speed is 1 Å/s, and a time is 1000 s, to form a cathode with a thickness of 100 nm.

In step S28, a photoelectric device is obtained after packaging.

### Photoelectric Device Examples 2-8

Photoelectric device Examples 2-8 are basically the same as Photoelectric device Example 1, and only the difference is that the composite material prepared by Example 1 is replaced separately by the composite material prepared by Examples 2-8 to prepare electronic transport layer.

### Photoelectric Device Examples 9-13

Photoelectric device Examples 9-13 are basically the same as Photoelectric device Example 1, and only the difference is that the materials of the electronic transport layer in Photoelectric device Examples 9-13 is the magnesium-doped zinc oxide ZnMgO, which does not contain the doped carbon dots; and the material of the hole transport layer is replaced separately by the composite material prepared by Examples 9-13.

### Photoelectric Device Examples 14-17

Photoelectric device Examples 14-17 are basically the same as Photoelectric device Example 1, and only the difference is that the materials of the electronic transport layer in Photoelectric device Examples 14-17 is the magnesium-doped zinc oxide ZnMgO, which does not contain the doped carbon dots; and the material of the luminescent layer is replaced separately by the composite material prepared by Examples 14-17.

### Photoelectric Device Example 18

Photoelectric device Example 18 is basically the same as Photoelectric device Example 2, and only the difference is that the material of the hole transport layer is replaced by the composite material prepared by Example 10.

### Photoelectric Device Example 19

Photoelectric device Example 19 is basically the same as Photoelectric device Example 2, and only the difference is that the material of the luminescent layer is replaced by the composite material prepared by Example 15.

### Photoelectric Device Example 20

Photoelectric device Example 20 is basically the same as Photoelectric device Example 10, and only the difference is that the material of the luminescent layer is replaced by the composite material prepared by Example 15.

### Photoelectric Device Example 21

Photoelectric device Example 21 is basically the same as Photoelectric device Example 18, and only the difference is that the material of the luminescent layer is replaced by the composite material prepared by Example 15.

### Photoelectric Device Example 22

Photoelectric device Example 22 is basically the same as Photoelectric device Example 1, and only the difference is that the materials of the electronic transport layer in Photoelectric device Example 22 is the magnesium-doped zinc oxide ZnMgO, which does not contain the doped carbon dots. After the hole transport layer is formed, it further including: a zinc-doped carbon dots dispersion is provided, which contained zinc-doped carbon dots with a zinc doping content of 5%; and the dispersion is spin-coated on the hole transport layer to form a second interface sub-layer with a thickness of 5 nm, and the luminescent layer is formed on the second interface sub-layer.

### Photoelectric Device Example 23

Photoelectric device Example 23 is basically the same as Photoelectric device Example 1, and only the difference is that the materials of the electronic transport layer in Photoelectric device Example 23 is the magnesium-doped zinc oxide ZnMgO, which does not contain the doped carbon dots. After the luminescent layer is formed, it further including: a zinc-doped carbon dots dispersion is provided, which contained zinc-doped carbon dots with a zinc doping content of 5%; and the dispersion is spin-coated on the luminescent layer to form a third interface sub-layer with a thickness of 5 nm, and the electronic transport layer is formed on the third interface sub-layer.

### Photoelectric Device Example 24

Photoelectric device Example 24 is basically the same as Photoelectric device Example 22, and only the difference is that after the luminescent layer is formed, it further including: a zinc-doped carbon dots dispersion is provided, which contained zinc-doped carbon dots with a zinc doping content of 5%; and the dispersion is spin-coated on the luminescent layer to form a third interface sub-layer with a thickness of 5 nm, and the electronic transport layer is formed on the third interface sub-layer.

### Photoelectric Device Example 25

Photoelectric device Example 25 is basically the same as Photoelectric device Example 20, and only the difference is that after the hole transport layer is formed, it further including: a zinc-doped carbon dots dispersion is provided, which contained zinc-doped carbon dots with a zinc doping content of 5%; and the dispersion is spin-coated on the hole transport layer to form a second interface sub-layer with a thickness of 5 nm, and the luminescent layer is formed on the second interface sub-layer.

### Photoelectric Device Example 26

Photoelectric device Example 26 is basically the same as Photoelectric device Example 19, and only the difference is that after the luminescent layer is formed, it further including: a zinc-doped carbon dots dispersion is provided, which contained zinc-doped carbon dots with a zinc doping content of 5%; and the dispersion is spin-coated on the luminescent layer to form a third interface sub-layer with a thickness of 5 nm, and the electronic transport layer is formed on the third interface sub-layer.

### Photoelectric Device Example 27

Photoelectric device Example 27 is basically the same as Photoelectric device Example 21, and only the difference is that after the hole transport layer is formed, it further including: a zinc-doped carbon dots dispersion is provided, which contained zinc-doped carbon dots with a zinc doping content of 5%; and the dispersion is spin-coated on the hole transport layer to form a second interface sub-layer with a thickness of 5 nm, and the luminescent layer is formed on the second interface sub-layer. And after the luminescent layer is formed, it further including: a zinc-doped carbon dots dispersion is provided, which contained zinc-doped carbon dots with a zinc doping content of 5%; and the dispersion is spin-coated on the luminescent layer to form a third interface sub-layer with a thickness of 5 nm, and the electronic transport layer is formed on the third interface sub-layer.

### Photoelectric Device Example 28

Photoelectric device Example 28 is basically the same as Photoelectric device Example 1, and only the difference is that the materials of the electronic transport layer in Photoelectric device Example 28 is the magnesium-doped zinc oxide ZnMgO, which does not contain the doped carbon dots. After the ITO anode is formed, it further including: a zinc-doped carbon dots dispersion is provided, which contained zinc-doped carbon dots with a zinc doping content of 5%; and the dispersion is spin-coated on the ITO anode to form a first interface layer with a thickness of 5 nm, and the hole injection is formed on the first interface layer.

### Photoelectric Device Example 29

Photoelectric device Example 29 is basically the same as Photoelectric device Example 1, and only the difference is that the materials of the electronic transport layer in Photoelectric device Example 29 is the magnesium-doped zinc oxide ZnMgO, which does not contain the doped carbon dots. After the electronic injection layer is formed, it further including: a zinc-doped carbon dots dispersion is provided, which contained zinc-doped carbon dots with a zinc doping content of 5%; and the dispersion is spin-coated on the electronic injection layer to form a second interface layer with a thickness of 5 nm, and the cathode is formed on the second interface layer.

### Photoelectric Device Example 30

Photoelectric device Example 30 is basically the same as Photoelectric device Example 1, and only the difference is that the materials of the electronic transport layer in Photoelectric device Example 30 is the magnesium-doped zinc oxide ZnMgO, which does not contain the doped carbon dots. After the hole injection layer is formed, it further including: a zinc-doped carbon dots dispersion is provided, which contained zinc-doped carbon dots with a zinc doping content of 5%; and the dispersion is spin-coated on the hole injection layer to form a first interface sub-layer with a thickness of 5 nm, and the hole transport layer is formed on the first interface sub-layer.

### Photoelectric Device Example 31

Photoelectric device Example 31 is basically the same as Photoelectric device Example 1, and only the difference is that the materials of the electronic transport layer in Photoelectric device Example 31 is the magnesium-doped zinc oxide ZnMgO, which does not contain the doped carbon dots. After the electronic transport layer is formed, it further including: a zinc-doped carbon dots dispersion is provided, which contained zinc-doped carbon dots with a zinc doping content of 5%; and the dispersion is spin-coated on the electronic transport layer to form a fourth interface sub-layer with a thickness of 5 nm, and the electronic injection layer is formed on the fourth interface sub-layer.

### Photoelectric Device Example 32

Photoelectric device Example 32 is basically the same as Photoelectric device Example 24, and only the difference is that in Photoelectric device Example 32, further including: a first interface layer, a second interface layer, a first interface sub-layer and a fourth interface sub-layer are formed according to Photoelectric device Examples 28-31.

### Photoelectric Device Example 33

Photoelectric device Example 33 is basically the same as Photoelectric device Example 27, and only the difference is that in Photoelectric device Example 33, further including: a first interface layer, a second interface layer, a first interface sub-layer and a fourth interface sub-layer are formed according to Photoelectric device Examples 28-31.

### Photoelectric Device Comparative Example 1

Photoelectric device Comparative Example 1 is basically the same as Photoelectric device Example 1, and only the difference is that the composite material prepared by Example 1 is replaced by the material prepared by Comparative Example 1 to prepare electronic transport layer.

### Photoelectric Device Comparative Example 2

Photoelectric device Comparative Example 2 is basically the same as Photoelectric device Comparative Example 1, and only the difference is that the material (TFB) of the hole transport layer is replaced by the material (NiO) prepared by Comparative Example 5.

### Photoelectric Device Comparative Example 3

Photoelectric device Comparative Example 3 is basically the same as Photoelectric device Example 1, and only the difference is that the material of the electronic transport layer is replaced by the material prepared by Comparative Example 2, the material of the hole transport layer is replaced by the material prepared by Comparative Example 4, and the material of the luminescent layer is replaced by the material prepared by Comparative Example 8. Performance test:

The luminance (L), external quantum efficiency (EQE), voltage difference (VD) and lifetime T95@ 1000 nit of the photoelectric devices in Photoelectric device Examples 1-33 and Photoelectric device Comparative Examples 1-3 are tested respectively, and the results are shown in Table 2.

The luminance (L) is measured by photometer after the photoelectric device is stable.

The external quantum efficiency (EQE) is an important parameter to measure the quality of electroluminescent devices, which could be measured by EQE optical testing instrument. The external quantum efficiency represents the ratio of the electron-hole logarithm injected into a quantum dot to the number of photons emitted, and the unit is %. The specific calculation formula is as follows:

$$EQE = η e η r 𝒳 \frac{{K}_{R}}{{K}_{R} + {K}_{NR}} .$$

Where ne is the light output coupling efficiency, nr is the ratio of the number of recombination carriers to the number of injected carriers, x is the ratio of the number of excitons generating photons to the total number of excitons, KR is the radiation process rate, and K_{NR} is the non-radiation process rate. The test was carried out at room temperature, and the air humidity was 30%-60%.

The voltage difference (V D) could reflect the stability of the photoelectric device. When the photoelectric device is driven by constant current, the time required for the luminance to decrease to a certain proportion of the highest luminance, and the time for the luminance to decrease to 95% of the highest luminance is defined as T95. The voltage at T95 and the minimum voltage when the device is running are measured, and the difference is the voltage difference.

When photoelectric device is driven by constant current, the time when the luminance drops to 95% of the highest luminance is defined as T95, which indicates the measured lifetime. In order to shorten the test period, the photoelectric device lifetime test is usually carried out by accelerating the aging of the photoelectric device under high luminance, and the lifetime under high luminance is obtained by fitting the extended exponential decay luminance attenuation formula, for example, the lifetime at 1000 nit is T95@ 1000 nit. The specific calculation formula is as follows:

$$T 9 {5}_{L} = T {95}_{H} \cdot {( \frac{{L}_{H}}{{L}_{L}} )}^{A} .$$

Where T95_{L} is the lifetime under low luminance, T95_{H} is the measured lifetime under high luminance, L_{H} is the acceleration of the device to the highest luminance, L_{L} is 1000 nit, and A is the acceleration factor. In this experiment, the lifetime of several groups of QLED devices under rated luminance is measured and the value of A is 1.7.

TABLE 2

| | L | EQE | VD | T95@1000 nit |
|---|---|---|---|---|
| | (cd/m²) | (%) | (V) | (h) |
| Photoelectric device Example 1 | 30000 | 20 | 0.5 | 14200 |
| Photoelectric device Example 2 | 35200 | 23.1 | 0.3 | 17800 |
| Photoelectric device Example 3 | 29300 | 19.5 | 0.5 | 14000 |
| Photoelectric device Example 4 | 26200 | 18.2 | 0.6 | 13200 |
| Photoelectric device Example 5 | 26700 | 18.7 | 0.5 | 13500 |
| Photoelectric device Example 6 | 27900 | 19.1 | 0.6 | 13800 |
| Photoelectric device Example 7 | 27500 | 18.7 | 0.5 | 13700 |
| Photoelectric device Example 8 | 28300 | 19.4 | 0.6 | 13600 |
| Photoelectric device Example 9 | 27000 | 17 | 0.5 | 14100 |
| Photoelectric device Example 10 | 31200 | 21.5 | 0.6 | 15800 |
| Photoelectric device Example 11 | 25100 | 16.1 | 0.5 | 13300 |
| Photoelectric device Example 12 | 25800 | 16.5 | 0.5 | 13600 |
| Photoelectric device Example 13 | 26500 | 16.9 | 0.4 | 14500 |
| Photoelectric device Example 14 | 29000 | 18 | 0.5 | 14400 |
| Photoelectric device Example 15 | 36000 | 24 | 0.4 | 21500 |
| Photoelectric device Example 16 | 27100 | 18.2 | 0.4 | 13200 |
| Photoelectric device Example 17 | 28600 | 19 | 0.4 | 13940 |
| Photoelectric device Example 18 | 37800 | 25.1 | 0.3 | 25400 |
| Photoelectric device Example 19 | 37500 | 25.2 | 0.3 | 25100 |
| Photoelectric device Example 20 | 36900 | 24.6 | 0.5 | 24900 |
| Photoelectric device Example 22 | 39800 | 25.5 | 0.2 | 26800 |
| Photoelectric device Example 22 | 25410 | 18.3 | 0.6 | 13700 |
| Photoelectric device Example 23 | 25900 | 18.4 | 0.6 | 14000 |
| Photoelectric device Example 24 | 26780 | 20.7 | 0.5 | 16400 |
| Photoelectric device Example 25 | 31400 | 24.7 | 0.3 | 22700 |
| Photoelectric device Example 26 | 32840 | 25.1 | 0.3 | 23400 |
| Photoelectric device Example 27 | 40500 | 29.4 | 0.2 | 28700 |
| Photoelectric device Example 18 | 24950 | 17.6 | 0.5 | 13500 |
| Photoelectric device Example 19 | 24760 | 17.5 | 0.4 | 12900 |
| Photoelectric device Example 30 | 24400 | 17.3 | 0.6 | 13600 |
| Photoelectric device Example 31 | 25100 | 17.7 | 0.4 | 13400 |
| Photoelectric device Example 32 | 28430 | 21.8 | 0.2 | 18700 |
| Photoelectric device Example 33 | 41700 | 30.5 | 0.2 | 30100 |
| Photoelectric device | 23200 | 13 | 1.2 | 11000 |
| Comparative Example 1 | | | | |
| Photoelectric device | 24000 | 14.5 | 0.9 | 10200 |
| Comparative Example 2 | | | | |
| Photoelectric device | 24500 | 17.1 | 0.8 | 12400 |
| Comparative Example 3 | | | | |

From Photoelectric device Examples 1-8 and Photoelectric device Comparative Example 1, it could be seen that the composite material of the doped carbon dots modified the n-type semiconductor material is applied to the electronic transport layer of photoelectric devices, which could effectively improve the luminance, external quantum efficiency and service life of photoelectric devices, and reduce the voltage increase, indicating that the stability of the photoelectric devices has been improved. Corresponding to the current density results of Example 2, the performance of the photoelectric device of Photoelectric device Example 2 is outstanding.

From Photoelectric device Examples 9-13 and Photoelectric device Comparative Examples 1-2, it could be seen that the performance of the composite materials applied to the hole transport layer is slightly worse than the composite materials applied to electronic transport layer in Photoelectric device Examples 1-8, but compared with Photoelectric device Comparative Examples 1-2, the performance of Photoelectric device Examples 9-13 is also improved.

From Photoelectric device Examples 14-17 and Photoelectric device Comparative Example 1, the application of the doped carbon dots modified luminescent materials to the luminescent layer improves the luminance, external quantum efficiency, service life and reduces the voltage difference of the photoelectric devices, and the luminance of the Photoelectric device Example 15 is relatively high, which is due to the good compatibility between cadmium-doped carbon dots and quantum dot luminescent material, and the carbon dots itself has luminescent properties.

From Photoelectric device Examples 2, 10, 15 and 18-21, Photoelectric device Comparative Examples 1, 3, on the whole, the performance of Photoelectric device Examples 18-21 is better than that of Photoelectric device Comparative Examples 1, 3 and other photoelectric device examples, mainly because at least two functional layers adopt the composite material of the application, in which the electronic transport layer, the luminescent layer and the hole transport layer of Photoelectric device Example 21 all adopt the composite materials of the application and the performance of the photoelectric device is significantly improved. In Photoelectric device Comparative Example 3, carbon dots modified composite material is used as the material of the functional layer, compared with the Photoelectric device Comparative Examples 1-2, the performance of the photoelectric device is improved, but the performance improvement is still limited, which is far inferior to the photoelectric device examples provided by this application.

From the Photoelectric device Examples 22-33 and Photoelectric device Comparative Example 1, it could be seen that setting an interface layer formed by the doped carbon dots between adjacent film layers in the photoelectric device could effectively improve the luminance and external quantum efficiency of the photoelectric device, reduce the voltage difference and prolong the service life. The effect of setting a multi-layer interface layer is better than that of the photoelectric device with only one interface layer, such as Photoelectric device Example 24 is better than that of Photoelectric device Examples 22-23, and the effect of the Photoelectric device Example 32 is better than that of Photoelectric device Examples 28-31. In Photoelectric device Examples 25-27 and Photoelectric device Example 33, the interface layer is set and composite materials are applied to the functional layer at the same time, and the performance of photoelectric devices is significantly improved, especially in Photoelectric device Example 33, the luminance and external quantum efficiency of photoelectric devices are significantly improved, and the voltage difference is significantly reduced, which indicated that the stability of photoelectric devices is improved and the service life is correspondingly prolonged.

Composite material and photoelectric device are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

What is claimed is:

1. A composite material, comprising:
a host material; and
a modification material;
wherein the host material comprises semiconductor material, and the modification material comprises doped carbon dots.

2. The composite material according to claim 1, wherein a mass ratio of the host material to the modification material is (5-50): 1.

3. The composite material according to claim 1, wherein the doped carbon dots comprise carbon dots and doping element, and the doping element is selected from one or more of alkali metal, alkaline earth metal, IIB group element and VIA group element.

4. The composite material according to claim 3, wherein an average particle size of the carbon dots ranges between 2 nm-10 nm;
the alkali metal comprises K; the alkaline earth metal comprises Mg; the IIB group element comprises one or more of Cd and Zn; and the VIA group element comprises one or more of Se and S;
a doping mass fraction of the doping element in the doped carbon dots ranges between 1 wt %-20 wt %; and
the doping element in the doped carbon dots comprises at least one of the alkali metal, the alkaline earth metal and at least one of the IIB group element and the VIA group element, a mass ratio of the mass sum of the alkali metal and the alkaline earth metal to the mass sum of the IIB group element and the VIA group element is (1-3):(1-3).

5. The composite material according to claim 1, wherein an active group is connected with the doped carbon dots.

6. The composite material according to claim 5, wherein the active group is selected from one or more of amino group, carboxyl group, hydroxyl group, sulfhydryl group, carbonyl group, quinone group, pyrrole group and pyridyl group.

7. The composite material according to claim 1, wherein the semiconductor material comprises one or more of n-type semiconductor material, p-type semiconductor material and luminescent material.

8. The composite material according to claim 7, wherein the n-type semiconductor material is selected from one or more of 8-hydroxyquinoline aluminum, 1,3,5-tris (1-phenyl-1H-benzimidazole-2-yl)benzene, 4,7-diphenyl-1,10-o-phenanthroline, 2,9-dimethyl-4,7-diphenyl-1,10-phenanthroline, 3-(biphenyl-4-yl)-5-(4-tert-butylphenyl)-4-phenyl-4H-1,2,4-triazole, bis (2-methyl-8-hydroxyquinoline-N1,O8)-(1,1′-biphenyl-4-hydroxy) aluminium, first doped metal oxide particle, bis(2-methyl-8-hydroxyquinoline-N1,O8)-(1,1′-biphenyl-4-hydroxy) aluminum, 2,2′-(1,3-phenyl) bis [5-(4-tert-butylphenyl)-1,3,4-oxadiazole], tri [2,4,6-trimethyl-3-(3-pyridyl)phenyl] borane, tetrakis [(m-pyridyl)-benzene-3-yl] biphenyl, 3,3′-[5′-[3-(3-pyridyl)phenyl] [1,1′: 3′, 1′-terphenyl]-3,3″-diyl] bipyridine, 1,3-bis(3,5-bipyridine-3-yl phenyl)benzene, n,n′-bis(naphthalene-1-yl)-n,n′-bis(phenyl)benzidine, first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS;
the p-type semiconductor material is selected from one or more of 4,4′-N,N′-dicarbazolyl-biphenyl, N,N′-diphenyl-N, N′-bis(1-naphthyl)-1,1′-biphenyl)-4,4′-diamine, N, N′-bis(3-methylphenyl)-N,N′-bis(phenyl)-spiro, N,N′-bis(4-(N,N′-diphenyl-amino)phenyl)-N,N′-diphenylbenzidine, 4,4′, 4′-tris (N-carbazolyl)-triphenylamine, 4,4′, 4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′,4′-tris (N-3-methylphenyl-N-phenylamino) triphenylamine, poly [(9,9′-dioctyl fluorene-2,7-diyl)-co-(4, 4′-(N-(4-sec-butylphenyl)diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly (9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nanocrystalline diamond, microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride; and
the luminescent material is selected from one or more of organic luminescent material and quantum dot luminescent material; and a material of the organic luminescent material is selected from one or more of CBP:Ir(mppy)₃, TCTX:Ir(mmpy), diarylanthracene derivatives, stilbene aromatic derivatives, pyrene derivatives, fluorene derivatives, TBPe fluorescent materials, TTPX fluorescent materials, TB Rb fluorescent materials, DBP fluorescent materials, delayed fluorescent materials, TTA materials, TADF materials, polymers containing B-N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot is respectively selected from one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, AlN, AIP, AlAs, AlSb, InN, InP, InAs, InSb, GaNP, GaNAs, GaNSb, GaPAs, GaPSb, AlNP, AlNAs, AlNSb, AIPAS, AIPSb, InNP, InNAs, InNSb, InPAs, InPSb, GaAlNP, GaAlNAs, GaAlNSb, GaAlPAs, GaAIPSb, GalnNP, GalnNAs, GalnNSb, GalnPAs, GalnPSb, InAINP, InAINAs, InAlNSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻; the general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.

9. The composite material according to claim 5, wherein the luminescent material is selected from quantum dot luminescent material, and the doped carbon dots and the quantum dot luminescent material are connected through the active group.

10. A photoelectric device, comprising:
an anode;
a cathode;
a functional layer, between the anode and the cathode; wherein a material of the functional layer comprises composite material, and the composite material comprises a host material and a modification material, the host material comprises semiconductor material, and the modification material comprises first doped carbon dots.

11. The photoelectric device according to claim 10, wherein the photoelectric device further comprises an interface layer; the functional layer comprises a plurality of sub-functional layers; and the interface layer comprises one or more of a first interface layer located between the anode and the functional layer, a second interface layer located between the functional layer and the cathode and a third interface layer located between two adjacent the sub-functional layers; and a material of the first interface layer comprises second doped carbon dots, a material of the second interface layer comprises third doped carbon dots, and a material of the third interface layer comprises fourth doped carbon dots.

12. The photoelectric device according to claim 11, wherein a doping mass fraction of a doping element in the first doped carbon dots ranges between 1 wt %-20 wt %; a doping mass fraction of a doping element in the second doped carbon dots ranges between 1 wt %-20 wt %; a doping mass fraction of a doping element in the third doped carbon dots ranges between 1 wt %-20 wt %; a doping mass fraction of a doping element in the fourth doped carbon dots ranges between 1 wt %-20 wt %; and
a doping element in the first doped carbon dots, a doping element in the second doped carbon dots, a doping element in the third doped carbon dots, and a doping element in the fourth doped carbon dots is each independently selected from one or more of alkali metal, alkaline earth metal, IIB group element and VIA group element; and the alkali metal comprises K, the alkaline earth metal comprises Mg, the IIB group element comprises one or more of Cd and Zn, and the VIA group element comprises one or more of Se and S.

13. The photoelectric device according to claim 10, wherein the functional layer comprises one or more of a hole functional layer, a luminescent layer and an electronic functional layer, wherein the hole functional layer is arranged between the anode and the luminescent layer, and the electronic functional layer is arranged between the luminescent layer and the cathode.

14. The photoelectric device according to claim 13, wherein the semiconductor material comprises n-type semiconductor material, p-type semiconductor material and luminescent material; the material of the hole functional layer comprises the composite material, the host material in the composite material is the p-type semiconductor material; the material of the luminescent layer comprises the composite material, the host material in the composite material is the luminescent material; the material of the electronic functional layer comprises the composite material, the host material in the composite material is the n-type semiconductor material; and
the hole functional layer comprises one or more of a hole injection layer and a hole transport layer, and the hole injection layer is located between the anode and the hole transport layer; the electronic functional layer comprises one or more of an electronic injection layer and an electronic transport layer, and the electronic injection layer is located between the electronic transport layer and the cathode.

15. The photoelectric device according to claim 11, wherein the hole functional layer comprises one or more of a hole injection layer and a hole transport layer, and the hole injection layer is located between the anode and the hole transport layer; the electronic functional layer comprises one or more of an electronic injection layer and an electronic transport layer, and the electronic injection layer is located between the electronic transport layer and the cathode; and
the third interface layer comprises one or more of a first interface sub-layer between the hole injection layer and the hole transport layer, a second interface sub-layer between the hole transport layer and the luminescent layer, a third interface sub-layer between the luminescent layer and the electronic transport layer, and a fourth interface sub-layer between the electronic transport layer and the electronic injection layer.

16. The photoelectric device according to claim 12, wherein a material of the first electrode and the second electrode is each independently selected from one or more of metal, carbon material and metal oxide, and the metal is selected from one or more of Al, Ag, Cu, Mo, Au, Ba, Ca, Y b and Mg, and the carbon material is selected from one or more of graphite, carbon nanotubes, graphene and carbon fiber, and the metal oxide is selected from one or more of metal oxide electrode or composite electrode with metal sandwiched between doped or undoped transparent metal oxide, and a material of the metal oxide electrode is selected from one or more of ITO, FTO, ATO, AZO, GZO, IZO, MZO, MoO₃ and AMO, and the composite electrode is selected from one or more of AZO/Ag/AZO, AZO/Al/AZO, ITO/Ag/ITO, ITO/Al/ITO, ZnO/Ag/ZnO, ZnO/Al/ZnO, ZnS/Ag/ZnS, ZnS/Al/ZnS, TiO₂/Ag/TiO₂ and TiO₂/Al/TiO₂.

17. A photoelectric device, comprising:
an anode;
a cathode;
a functional layer, between the anode and the cathode, and comprises a plurality of sub-functional layers; and
an interface layer which comprise one or more of a first interface layer located between the anode and the functional layer, a second interface layer located between the functional layer and the cathode and a third interface layer located between two adjacent the sub-functional layers; and a material of the first interface layer comprises second doped carbon dots, a material of the second interface layer comprises third doped carbon dots, and a material of the third interface layer comprises fourth doped carbon dots.

18. The photoelectric device according to claim 17, wherein a doping mass fraction of a doping element in the second doped carbon dots ranges between 1 wt %-20 wt %; a doping mass fraction of a doping element in the third doped carbon dots ranges between 1 wt %-20 wt %; a doping mass fraction of a doping element in the fourth doped carbon dots ranges between 1 wt %-20 wt %; and
a doping element in the second doped carbon dots, a doping element in the third doped carbon dots, and a doping element in the fourth doped carbon dots is each independently selected from one or more of alkali metal, alkaline earth metal, IIB group element and VIA group element; and the alkali metal comprises K, the alkaline earth metal comprises Mg, the IIB group element comprises one or more of Cd and Zn, and the VIA group element comprises one or more of Se and S.

19. The photoelectric device according to claim 17, wherein the functional layer comprises one or more of a hole functional layer, a luminescent layer and an electronic functional layer, wherein the hole functional layer is arranged between the anode and the luminescent layer, and the electronic functional layer is arranged between the luminescent layer and the cathode;
the hole functional layer comprises one or more of a hole injection layer and a hole transport layer, and the hole injection layer is located between the anode and the hole transport layer; the electronic functional layer comprises one or more of an electronic injection layer and an electronic transport layer, and the electronic injection layer is located between the electronic transport layer and the cathode; and
the third interface layer comprises one or more of a first interface sub-layer between the hole injection layer and the hole transport layer, a second interface sub-layer between the hole transport layer and the luminescent layer, a third interface sub-layer between the luminescent layer and the electronic transport layer, and a fourth interface sub-layer between the electronic transport layer and the electronic injection layer.

20. The photoelectric device according to claim 19, wherein a material of the electronic functional layer is selected from one or more of 8-hydroxyquinoline aluminum, 1,3,5-tris (1-phenyl-1H-benzimidazole-2-yl)benzene, 4,7-diphenyl-1,10-o-phenanthroline, 2,9-dimethyl-4,7-diphenyl-1,10-phenanthroline, 3-(biphenyl-4-yl)-5-(4-tert-butylphenyl)-4-phenyl-4H-1,2,4-triazole, bis(2-methyl-8-hydroxyquinoline-N1,O8)-(1,1′-biphenyl-4-hydroxy) aluminium, first doped metal oxide particle, bis(2-methyl-8-hydroxyquinoline-N1,O8)-(1,1′-biphenyl-4-hydroxy) aluminum, 2,2′-(1,3-phenyl) bis [5-(4-tert-butylphenyl)-1,3,4-oxadiazole], tri [2,4,6-trimethyl-3-(3-pyridyl)phenyl] borane, tetrakis [(m-pyridyl)-benzene-3-yl] biphenyl, 3,3′-[5′-[3-(3-pyridyl)phenyl] [1,1′: 3′, 1′-terphenyl]-3,3″-diyl] bipyridine, 1,3-bis(3,5-bipyridine-3-yl phenyl)benzene, n,n′-bis(naphthalene-1-yl)-n,n′-bis(phenyl)benzidine, first doped metal oxide particle, first undoped metal oxide particle, IIB-VIA semiconductor material, IIIA-VA semiconductor material and IB-IIIA-VIA semiconductor material, and a material of the first undoped metal oxide particle is selected from one or more of ZnO, TiO₂, SnO₂, ZrO₂ and Ta₂O₅, and a metal oxide in the first doped metal oxide particle is selected from one or more of ZnO, TiO₂, SnO₂, ZrO₂, Ta₂O₅ and Al₂O₃, and a doping element in the first doped metal oxide particle is selected from one or more of Al, Mg, Li, Mn, Y, La, Cu, Ni, Zr, Ce, In and Ga, and the IIB-VIA semiconductor material is selected from one or more of ZnS, ZnSe and CdS, and the IIIA-VA semiconductor material is selected from one or more of InP and GaP, and the IB-IIIA-VIA family semiconductor material is selected from one or more of CuInS and CuGaS;
a material of the hole functional layer is selected from one or more of 4,4′-N,N′-dicarbazolyl-biphenyl, N,N′-diphenyl-N, N′-bis(1-naphthyl)-1,1′-biphenyl)-4,4′-diamine, N, N′-bis(3-methylphenyl)-N,N′-bis(phenyl)-spiro, N,N′-bis(4-(N,N′-diphenyl-amino)phenyl)-N,N′-diphenylbenzidine, 4,4′, 4′-tris (N-carbazolyl)-triphenylamine, 4,4′, 4′-tris (carbazole-9-yl) triphenylamine, trichloroisocyanuric acid, terbium-doped phosphate-based green luminescent material, 2,3,6,7,10,11-hexacyano-1,4,5,8,9,12-hexaazaphenanthrene, 4,4′, 4′-tris (N-3-methylphenyl-N-phenylamino) triphenylamine, poly [(9,9′-dioctyl fluorene-2,7-diyl)-co-(4, 4′-(N-(4-sec-butylphenyl)diphenylamine))], poly (4-butylphenyl-diphenylamine), poly [bis(4-phenyl) (4-butylphenyl) amine], polyaniline, polypyrrole, poly (p) phenylene vinylene, poly (phenylene vinylene), poly [2-methoxy-5-(2-ethylhexyloxy)-1,4-phenylene vinylene], poly [2-methoxy-5-(3′,7′-dimethyl octyloxy)-1,4-phenylene vinylene], copper phthalocyanine, aromatic tertiary amine, 4,4′-bis (p-carbazolyl)-1,1′-biphenyl compound, N,N,N′,N′-tetraarylbenzidine, poly (9,9-dioctylfluorene-alt-N-(4-sec-butylphenyl)-diphenylamine), PEDOT, PEDOT:PSS and its derivatives, PEDOT:PSS derivatives doped with s-MoO₃, poly (N-vinylcarbazole) and its derivatives, polymethacrylate and its derivatives, poly (9,9-octylfluorene) and its derivatives, poly (spirofluorene) and its derivatives, N,N′-bis (naphthalene-1-yl)-N,N′-diphenylbenzidine, spiro NPB, nanocrystalline diamond,
microcrystalline cellulose, tetracyanoquinone dimethylmethane, doped graphene, undoped graphene, second doped metal oxide particle, second undoped metal oxide particle, metal sulfide, metal selenides and metal nitride, wherein a metal oxide in the second doped metal oxide particle and a metal oxide in the second undoped metal oxide particle is independently selected from one or more of MoO₃, WO₃, NiO, CrO₃, CuO and V₂O₅, and a doping element in the second doped metal oxide particle is selected from one or more of Mo, W, Ni, Cr, Cu and V, the metal sulfide is selected from one or more of CuS, MoS₃ and WS₃, the metal selenide is selected from one or more of MoSe₃ and WSe₃, and the metal nitride is selected from p-type gallium nitride; and
a material of the luminescent layer is selected from one or more of organic luminescent material and quantum dot luminescent material; and a material of the organic luminescent material is selected from one or more of CBP:Ir(mppy)₃, TCTX:Ir(mmpy), diarylanthracene derivatives, stilbene aromatic derivatives, pyrene derivatives, fluorene derivatives, TBPe fluorescent materials, TTPX fluorescent materials, TB Rb fluorescent materials, DBP fluorescent materials, delayed fluorescent materials, TTA materials, TADF materials, polymers containing B-N covalent bonds, HLCT materials and Exciplex luminescent materials, and the quantum dot luminescent material is selected from one or more of single-structure quantum dot, core-shell quantum dot and perovskite-type semiconductor material; a material of the single-structure quantum dot, a core material of the core-shell quantum dot and a shell material of the core-shell quantum dot is respectively selected from one or more of second II-VI compound, second IV-VI compound, second III-V compound and I-III-VI compound; and a shell layer of the core-shell structure quantum dot comprises one or more layers; the second II-VI compound is selected from one or more of CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe and HgZnSTe; the second IV-VI compound is selected from one or more of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe and SnPbSTe; the second III-V compound is selected from one or more of GaN, GaP, GaAs, GaSb, A IN, AIP, AlAs, AlSb, InN, InP, InAs, InSb, GaNP, GaNAs, GaNSb, GaPAs, GaPSb, AlNP, AlNAs, AlNSb, AIPAS, AIPSb, InNP, InNAs, InNSb, InPAs, InPSb, GaAINP, GaAlNAs, GaAlNSb, GaAlPAs, GaAIPSb, GalnNP, GalnNAs, GalnNSb, GalnPAs, GalnPSb, InAINP, InAINAs, InAlNSb, InAlPAs and InAlPSb; the I-III-VI compound is selected from one or more of CuInS₂, CuInSe₂ and AgInS₂; and the core-shell quantum dot is selected from one or more of CdSe/CdSeS/CdS, InP/ZnSeS/ZnS, CdZnSe/ZnSe/ZnS, CdSe/ZnS, CdSe/ZnSe, ZnSe/ZnS, ZnSe/ZnS, ZnSe/ZnS, and ZnSe/ZnSe/ZnSe; and the perovskite semiconductor material is selected from one of doped or undoped inorganic perovskite semiconductor or organic-inorganic hybrid perovskite semiconductor; a general structural formula of the inorganic perovskite semiconductor is AMX₃, wherein A is Cs⁺, and X is divalent metal cation, which is selected from one or more of Pb²⁺, Sn²⁺, Cu²⁺, Ni²⁺, Cd²⁺, Cr²⁺, Mn²⁺, Co²⁺, Fe²⁺, Ge²⁺, Yb²⁺ and Eu²⁺, and X is a halogen anion selected from one or more of Cl⁻, Br⁻ and I⁻; the general structural formula of the organic-inorganic hybrid perovskite semiconductor is BMX₃, wherein B is an organic amine cation selected from CH₃(CH₂)ₙ₋₂NH₃⁺ or [NH₃(CH₂)ₙNH₃]²⁺, wherein n≥2, and M is a divalent metal cation selected from Pb²⁺, Sn²⁺, Cu²⁺, Ni²⁺, Cd²⁺ and Cr³⁺, and X is a halogen anion selected from one or more of Cl⁻, Br⁻ and I⁻.
